(19) United States
(12) Patent Application Publication
(10) Pub. No.: US 2015/0314968 A1
(43) Pub. Date: Nov. 5, 2015

(54) Apparatus for Carrying and Transporting a Product

(71) Applicant: Technische Universiteit Delft, Delft (NL)

(72) Inventors: Ronald Adrianus Johannes Van Ostayen, Delft (NL); Robert Han Munnig Schmidt, Delft (NL); Vuong Hong Phuc, Delft (NL)

(21) Appl. No.: 14/702,446

(22) Filed: May 1, 2015

Related U.S. Application Data
(63) Continuation of application No. PCT/NL2013/050782, filed on Nov. 1, 2013.

(30) Foreign Application Priority Data
Nov. 6, 2012 (NL) 2009764

(51) Int. Cl. B65G 49/06; H01L 21/677; B65G 51/03

(52) U.S. Cl. CPC B65G 49/065; B65G 51/03; H01L 21/67784

(57) ABSTRACT

An apparatus for carrying and transporting a product, comprising a conveyor having a surface, which surface is during use directed towards the product and is provided with inlet openings and outlet openings for a medium for supporting and providing the product with traction, wherein the surface is divided into adjacent surface parts, and wherein the inlet openings and outlet openings are provided in the vicinity of the surface parts, and said adjacent surface parts are adjustable in height and/or form and/or shape so as to control the flow of the medium from the inlet openings to the outlet openings.

### CROSS-REFERENCE TO RELATED APPLICATIONS

This application is a continuation application of Patent Cooperation Treaty Application Serial No. PCT/NL2013/050782, filed on Nov. 1, 2013, which claims priority to Netherlands Patent Application No. 2009764, filed on Nov. 6, 2012, and the specifications and claims thereof are incorporated herein by reference.

### STATEMENT REGARDING FEDERALLY SPONSORED RESEARCH OR DEVELOPMENT

Not Applicable.

### INCORPORATION BY REFERENCE OF MATERIAL SUBMITTED ON A COMPACT DISC

Not Applicable.

### COPYRIGHTED MATERIAL

Not Applicable.

### BACKGROUND OF THE INVENTION

1. Field of the Invention (Technical Field)

The present invention relates to an apparatus for carrying and transporting a product, comprising a conveyor having a surface, which surface is during use directed towards the product and is provided with inlet openings and outlet openings for a medium for supporting and providing the product with traction, wherein the surface is divided into adjacent surface parts.

2. Description of Related Art

An apparatus is known from WO2008/026924 in the name of the applicant. The known apparatus has the inlet openings and outlet openings for the medium provided in the vicinity of the surface parts, and is designed for the transport of thin, fragile products. The products concerned include wafers, glass substrates, silicon solar cells, glass plates, displays and printing plates, whose dimensions and whose thickness may vary widely. As an example the dimensions of a substrate of 100×100 millimeters with a thickness of approximately 1 mm is mentioned.

US 2005/0050752 teaches a transfer apparatus for the transport of transfer objects such as glass substrates or semiconductor devices. In this apparatus a plurality of air nozzles inject air to hold a transfer object in place without said nozzles being in contact with the transfer object. The air nozzles can be manipulated in their orientation so as to provide a rest position to the transfer objects when the air nozzles are positioned perpendicular to it, and a traction force to move the transfer objects in a desired direction by inclining the air nozzles to a specified angle.

### BRIEF SUMMARY OF THE INVENTION

It is an object of the invention to provide alternative means for carrying and transporting a product, without compromising the properties and wide range of application possibilities of the known apparatus.

Further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention. In the drawings:

FIGS. 1A and 1B; 2A and 2B; 3A, 3B, and 3C; 4A, 4B, 4C, and 4D; 5; and 6A, 6B, 6C, 6D, 6E, and 6F each collectively elucidate a separate embodiment of the invention.

### DETAILED DESCRIPTION OF THE INVENTION

In a first aspect of the invention the outlet and inlet openings are stationary positioned in the surface and/or in or between the adjacent surface parts, which adjacent surface parts are adjustable in height and/or form and/or shape so as to manipulate a room left between each of the adjacent surface parts and the product so as to arrange a modification of flow resistance for the medium between each of the respective surface parts and the product in order to control the flow of the medium from the inlet openings to the outlet openings along the respective surface parts and to provide controlled traction to the product. The said inlet openings have a direct relation with the said outlet openings and the flow resistance between these inlet openings and outlet openings is controlled by adjusting the surface parts in between those inlet openings and outlet openings. This provides the advantage that a very direct and accurate control of the (direction of the) flow of the medium is possible without having to resort to inlet openings having an outlet with a variable direction for the medium, or to the application of (accurate) control valves in the feed lines for the medium to the inlet openings. The control of the (direction and quantity of the) flow between the inlet openings and outlet openings is directly influenced by merely manipulating the room left between the respective adjacent surface parts and the product. One notable advantage of the apparatus according to the invention is that the medium that flows from the inlet openings to the outlet openings can flow back in a closed circuit from the outlet openings to the inlet openings. This is beneficial in a clean room environment where it is important to keep out alien matter. It is remarked that the adjacent surface parts as such can have any shape, such as but not limited to a longitudinal shape, a square shape, a triangular shape, a hexagonal shape, a circular shape, or any combination thereof.

It is possible that the adjacent surface parts are physically separated from each other, although this is not necessary; in one embodiment the adjacent surface parts together constitute a unitary and deformable foil or sheet, wherein the adjacent surface parts are individually actuable.

In one embodiment of the invention each of the adjacent surface parts is uniformly adjustable in height.

In another more preferable embodiment of the invention the adjacent surface parts are adjustable so as to at least partly bend out of the plane of the surface towards or away from the product.

In this more preferable embodiment it is preferred that neighboring sides of adjacent surface parts bend out of the plane of the surface in opposite directions. This is beneficial when the outlet or inlet openings are positioned between these adjacent surface parts. Both adjacent surface parts can then work together in varying the opening degree of such openings.

In still another preferred embodiment the adjacent surface parts are each individually mounted on a flexible stem, which stem is bendable so as to effect bending out of the surface part that is mounted on said stem from the plane of the surface. This has benefits regarding the ease of control of bending the surface parts out of their plane. It is easy to apply mechanical, thermomechanical or electromechanical forces on the stem to effect the desired degree of bending out of the plane of the surface. As mentioned earlier, the shape of the adjacent surface parts can be tailored to the needs and requirements of the particular application.

Suitably each stem is provided with a channel for the medium. Preferably the channel in the stem is provided with an inlet opening for the medium.

Further in some embodiments it is preferable that each of the adjacent surface parts has an outlet opening or outlet openings for the medium on opposite sides of said surface parts. The outlet openings can then for instance connect to vacuum or low-pressure chambers to attract the flow of the medium.

In yet another embodiment each of the adjacent surface parts is mounted on a stem neighboring a channel or channels for the medium, wherein said surface parts are porous so as to operate as inlet openings for the medium. Actuation of the adjacent surface parts then arranges a modification of flow resistance for the medium between the said surface parts and the product so as to cause that said medium can flow with reduced resistance to a relatively thinner part of the space between these surface parts and the product. This embodiment is further suitably provided with a flexible gastight connection separating the medium flowing through the porous surface parts from the medium flowing through the outlet openings. The distribution of the flow in the area between the surface parts and the product is controlled by mechanical or electromechanical or other suitable means that directly act on the stems and cause that the surface parts mounted on said stems are bent out of the plane of the surface. This arranges an asymmetric flow of the medium between the surface parts and the product, and provides the product with the intended tractional force.

In the foregoing no mention has been made of the actuation means that can be applied for the control of the adjacent surface parts. In general all types of feasible actuation means can be applied but it is preferable that actuation of the adjacent surface parts is executed with actuation means selected from the group comprising thermal actuation means, mechanical actuation means and electromechanical actuation means. Mechanical actuation means can be implemented very simply and at low cost, whereas electromechanical actuation means are also available at low cost and provide high accuracy. Particularly piezo-ceramic actuators are usable.

As a further option according to the invention it is possible that the adjacent surface parts are divided into groups of jointly operated adjacent surface parts, wherein actuation means are applied that are individual to each of the groups. In this manner the complexity of the control of the apparatus can be kept low.

Another embodiment of the apparatus of the invention has the feature that the adjacent surface parts are separated by interpositioned walls and the inlet openings and outlet openings for the medium are provided in the surface parts. In this embodiment preferably the walls are adjustable in height and/or form and/or shape so as to control the flow of the medium from the inlet openings to the outlet openings.

The invention will hereinafter be further elucidated with reference to the drawing, showing schematic figure sets each representing an embodiment of the apparatus according to the invention. Whenever in the figures the same reference numerals are applied, these numerals refer to the same parts.

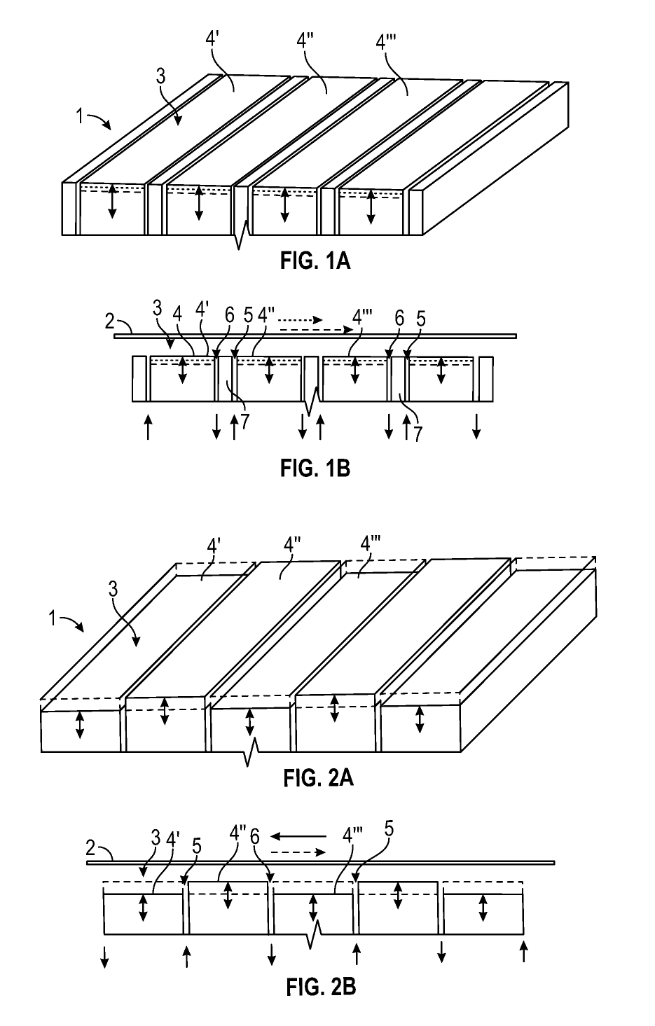

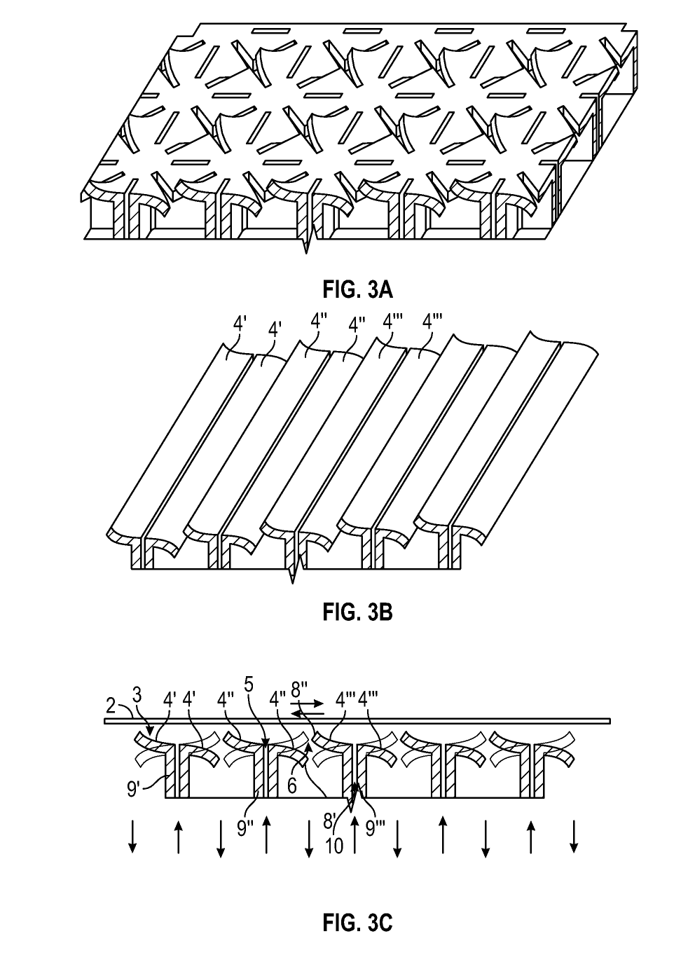

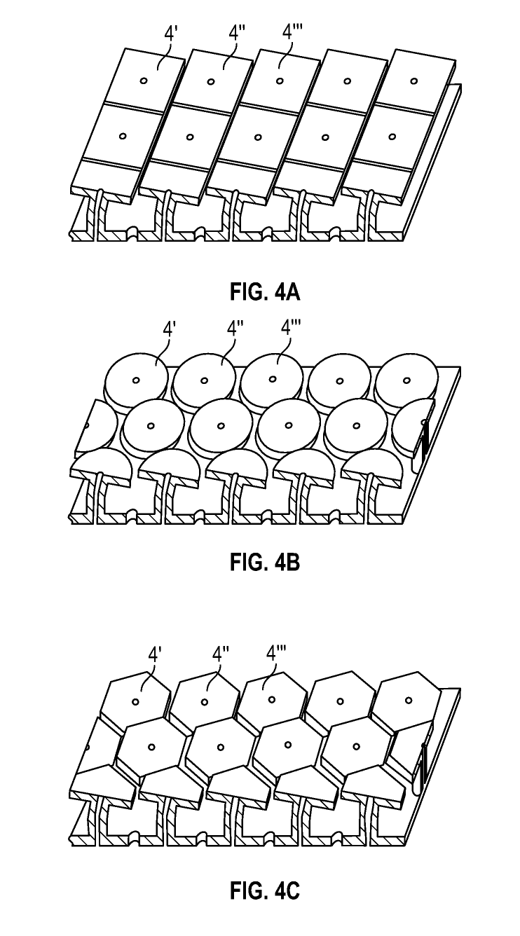

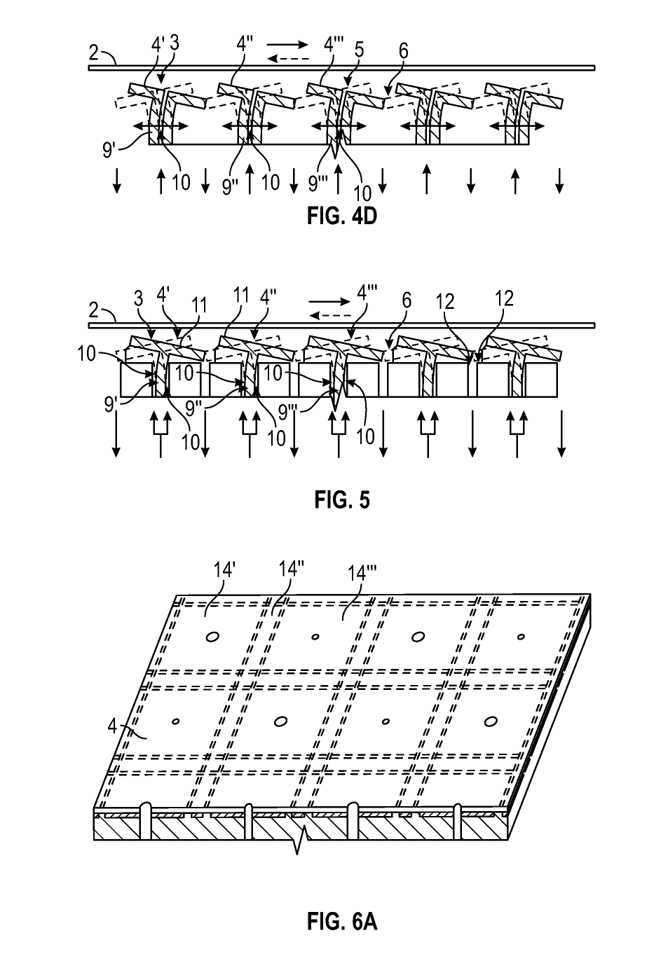

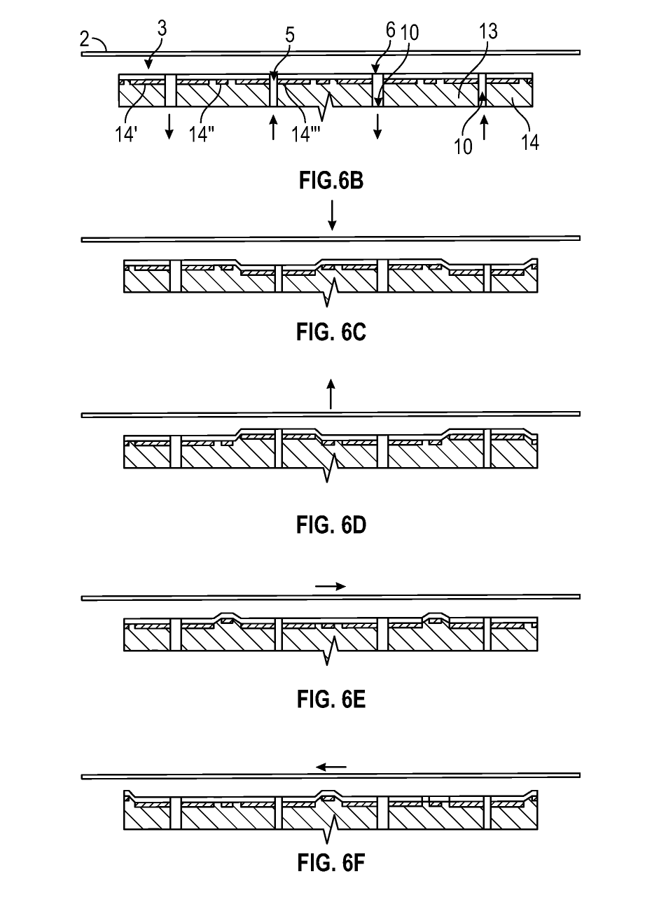

With reference first to FIGS. 1A and 1B and FIGS. 2A and 2B, an isometric view and a side view is provided of two different embodiments of the apparatus 1 for carrying and transporting a product 2 (only shown in the side view of both figures), comprising a conveyor 3 having a surface 4, which surface 4 is during use directed towards the product 2 and is provided with inlet openings 5 and outlet openings 6 for a medium for supporting and providing the product 2 with traction. The surface 4 is divided into adjacent surface parts 4′, 4″, 4′″. The inlet openings 5 and outlet openings 6 are provided in the vicinity of the surface parts 4′, 4″, 4′″, and said adjacent surface parts 4′, 4″, 4′″ are in the embodiments according to FIGS. 1A and 1B and FIGS. 2A and 2B adjustable in height so as to control the flow of the medium from the inlet openings 5 to the outlet openings 6. The sequence of the inlet openings 5 and the outlet openings 6 in the embodiment of FIGS. 1A and 1B with a fixed part 7 delimiting these openings 5, 6 requires that the functions of the inlet openings 5 and outlet openings 6 are interchanged when it is desired that the direction of traction applied to the product 2 is reversed. In the embodiment of FIGS. 2A and 2B changing the direction of traction applied to the product 2 can be more simply accomplished by changing the alteration in altitude levels of neighboring surface parts 4′, 4″, 4′″. This means that the surface parts 4′, 4″, 4′″ are moved from the position shown in solid lines to the position shown in dashed lines, or vice versa. The embodiments of FIGS. 1A and 1B and FIGS. 2A and 2B are very well suited to control the quantity of the flow of the medium from the inlet openings 5 to the outlet openings 6 due to their feature that the adjacent surface parts 4′, 4″, 4′″ are uniformly adjustable in height.

FIGS. 3A-C and 4A-D relate to embodiments in which the adjacent surface parts 4′, 4″, 4′″ are adjustable in form and/or shape which at least in part effects also their height with respect to the plane of the surface 4 so as to control the flow of the medium from the inlet openings 5 to the outlet openings 6. These embodiments of FIGS. 3A-C and 4A-D are particularly suitable to control the direction of the flow of the medium. For both embodiments the feature is present that the adjacent surface parts 4′, 4″, 4′″ are adjustable so as to at least partly bend out of the plane of the surface 4 towards or away from the product 2. Particularly it is shown that this results in that neighboring sides 8′, 8″ of adjacent surface parts 4′, 4″, 4′″ bend out of the plane of the surface 4 in opposite directions, thus providing an increased opening 6. For both embodiments further applies that each of the adjacent surface parts 4′, 4″, 4′″ is individually mounted on a stem 9′, 9″, 9′″.

The difference between the embodiment of FIG. 3 and the embodiment of FIGS. 4A-D is that in FIGS. 3A-C the stems 9′, 9″, 9′″ are rigid, whereas in FIGS. 4A-D the stems 9′, 9″, 9′″ are flexible. In the embodiment of FIGS. 3A-C bending out of the plane of the surface 4 therefore requires that the adjacent surface parts 4′, 4″, 4′″ themselves are actuated, for instance by implementing these surface parts 4′, 4″, 4′″ in a suitable piezo-ceramic material. By applying an appropriate electrical voltage the adjacent surface parts 4′, 4″, 4′″ can then be brought into the desired shape.

FIGS. 4A-D relate to the embodiment in which the adjacent surface parts 4′, 4″, 4′″ themselves are rigid but are each individually mounted on a flexible stem 9′, 9″, 9′″. Bending of the flexible stems 9′, 9″, 9′″ effects that the surface parts 4′, 4″, 4′″ mounted on said stems 9′, 9″, 9′″ are bent out of the plane of the surface 4. In this embodiment the actuation can be simply implemented by mechanical or electromechanical means that directly act on the stems 9′, 9″, 9′″.

In both the embodiment of FIGS. 3A-C and the embodiment of FIGS. 4A-D each stem 9′, 9″, 9′″ is further provided with a channel 10 for the medium and this channel 10 is provided with an inlet opening 5 for the medium at the surface 4. Also in both embodiments of FIGS. 3A-C and FIGS. 4A-D, each of the adjacent surface parts 4′, 4″, 4′″ has outlet openings 6 for the medium on opposite sides of said surface parts 4′, 4″, 4′″.

FIGS. 4A-C show three different isometric views representing different embodiments wherein each embodiment shows a different configuration/shape of the surface parts 4′, 4″, 4′″. This exemplifies that many variations are possible to the construction of the device of the invention without departing from the invention's spirit as embodied in the appended claims.

FIG. 5 shows an embodiment having the feature that each of the adjacent surface parts 4′, 4″, 4′″ is mounted on a stem 9′, 9″, 9′″ neighboring a channel or channels 10 for the medium, wherein said surface parts 4′, 4″, 4′″ are porous so as to operate as inlet openings for the medium. This embodiment is suitably provided with a flexible gastight connection 12 separating the medium flowing through the porous surface parts 4′, 4″, 4′″ from the medium flowing through the outlet openings 6.

The distribution of the flow in the area between the surface parts 4′, 4″, 4′″ and the product 2 is controlled by mechanical or electromechanical or other suitable means that directly act on the stems 9′, 9″, 9′″ and that cause that the surface parts 4′, 4″, 4′″ mounted on said stems 9′, 9″, 9′″ are bent out of the plane of the surface 4.

The most accurate and versatile control in the respective embodiments discussed hereinabove is available by arranging that each of the surface parts 4′, 4″, 4′″ is controlled individually. It may however be advantageous that the adjacent surface parts 4′, 4″, 4′″ are divided into groups of jointly operated adjacent surface parts, wherein actuation means are applied that are individual to each of the groups. This reduces the amount of control means that are required to make the apparatus operational. It also keeps the complexity of the apparatus of the invention relatively low.

In another embodiment that is shown in FIGS. 6A-F the apparatus has adjacent surface parts 14′, 14″, 14′″ that are separated by interpositioned walls and the inlet openings 5 and outlet openings 6 for the medium are provided in the surface parts 14′, 14″, 14′″. Preferably in this embodiment the walls are adjustable in height and/or form and/or shape so as to control the flow of the medium from the inlet openings 5 to the outlet openings 6. This provides several control possibilities, notably:

actuation only of those surface parts that are provided with an inlet opening 5, which arranges that more lifting power may be provided;

actuation only of those surface parts that are provided with an outlet opening 6, which arranges that the lifting power is decreased;

actuation of both the surface parts provided with an inlet opening and the surface parts that are provided with an outlet opening, which arranges more rigidity in the support of the product; and

actuation of two neighboring surface parts that are provided with an inlet opening and with an outlet opening, and actuation of the interpositioned wall, which arranges for control of the flow of the medium from the inlet to the outlet opening.

It is expressly pointed out that there are numerous variations possible within the scope of the appended claims and the corresponding invention. It is for instance remarked that although the above discussed figures substantially all exhibit symmetrical configurations of the apparatus according to the invention, it is likewise possible to embody the apparatus asymmetrically. The asymmetry may for instance relate to an off-center placement of the inlet for the medium with respect to the neighboring outlets. Also other variations to depart from the symmetry of the shown configurations are however possible.

Although the invention has been described in detail with particular reference to these preferred embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference.

What is claimed is:

1. An apparatus for carrying and transporting a product, comprising a conveyor having a surface, which surface is during use directed towards the product and is provided with inlet openings and outlet openings for a medium for supporting and providing the product with traction, wherein the surface is divided into adjacent surface parts, wherein the inlet and outlet openings are stationary and positioned in the surface and/or in or between the adjacent surface parts, which adjacent surface parts are adjustable in height and/or form and/or shape so as to manipulate a room left between each of the adjacent surface parts and the product so as to arrange a modification of flow resistance for the medium between the respective surface parts and the product in order to control the flow of the medium from the inlet openings to the outlet openings along the respective surface parts so as to provide controlled traction to the product.

2. The apparatus according to claim 1, wherein the adjacent surface parts together constitute a unitary and deformable foil or sheet, wherein the adjacent surface parts are individually actuable.

3. The apparatus according to claim 1, wherein the adjacent surface parts are adjustable to control the direction of the flow of the medium.

4. The apparatus according to claim 1, wherein each of the adjacent surface parts is uniformly adjustable in height.

5. The apparatus according to claim 1, wherein the adjacent surface parts are adjustable so as to at least partly bend out of the plane of the surface towards or away from the product.

6. The apparatus according to claim 5, wherein neighboring sides of adjacent surface parts bend out of the plane of the surface in opposite directions.

7. The apparatus according to claim 1, wherein the adjacent surface parts are each individually mounted on a flexible stem, which stem is bendable so as to effect bending out of the surface part mounted on said stem.

8. The apparatus according to claim 7, wherein each stem is provided with a channel for the medium.

9. The apparatus according to claim 8, wherein the channel is provided with an inlet opening for the medium.

10. The apparatus according to claim 5, wherein each of the adjacent surface parts has outlet openings for the medium in the vicinity of the surface parts on opposite sides of said surface parts.

11. The apparatus according to claim 5, wherein each of the adjacent surface parts is mounted on a stem neighboring a channel or channels for the medium, wherein said surface parts are porous so as to operate as inlet openings for the medium.

12. The apparatus according to claim 11, wherein actuation of the adjacent surface parts arranges a modification of flow resistance for the medium between the said surface parts and the product so as to cause that said medium can flow with reduced resistance to a relatively thinner part of the space between these surface parts and the product.

13. The apparatus according to claim 11, additionally comprising a flexible gastight connection separating the medium flowing through the porous surface parts from the medium flowing through the outlet openings.

14. The apparatus according to claim 1, wherein actuation of the adjacent surface parts is executed with actuation means selected from the group comprising thermal actuation means, mechanical actuation means and electromechanical actuation means.

15. The apparatus according to claim 1, wherein the adjacent surface parts are divided into groups of jointly operated adjacent surface parts, wherein actuation means are applied that are individual to each of the groups.

16. The apparatus according to claim 1, wherein the adjacent surface parts are separated by interpositioned walls and the inlet openings and outlet openings for the medium are provided in the surface parts.

17. The apparatus according to claim 16, wherein the walls are adjustable in height and/or form and/or shape so as to control the flow of the medium from the inlet openings to the outlet openings.
